(19) United States
(12) Patent Application Publication
(10) Pub. No.: US 2025/0336891 A1
(43) Pub. Date: Oct. 30, 2025

(54) SINGLE HYBRID SYSTEM-ON-CHIP (SOC) DIE STRUCTURE WITH HIGH MEMORY BANDWIDTH AND DENSITY

(71) Applicant: QUALCOMM Incorporated, San Diego, CA (US)

(72) Inventors: Woo Tag KANG, San Diego, CA (US); Zhongze WANG, San Diego, CA (US); Mustafa BADAROGLU, San Diego, CA (US); Periannan CHIDAMBARAM, San Diego, CA (US)

(21) Appl. No.: 18/815,446

(22) Filed: Aug. 26, 2024

Related U.S. Application Data
(60) Provisional application No. 63/638,822, filed on Apr. 25, 2024.

(51) Int. Cl. H01L 25/065; H01L 23/373; H10B 80/00

(52) U.S. Cl. CPC H01L 25/0657; H01L 23/3738; H10B 80/00; H01L 2225/06517

(57) ABSTRACT

A three-dimensional (3D) stacked chip package is described. The 3D stacked chip package includes a die having a wide input/output (IO) logic die area and a system-on-chip (SoC) logic die area isolated from the wide IO logic die area. The 3D stacked chip package also includes a memory stack on the wide IO logic area of the die. The 3D stacked chip package further includes a package substrate supporting the die.

### CROSS-REFERENCE TO RELATED APPLICATION

The present application claims the benefit of U.S. Provisional Patent Application No. 63/638,822, filed Apr. 25, 2024, and titled “SINGLE HYBRID SYSTEM-ON-CHIP (SOC) DIE STRUCTURE WITH HIGH MEMORY BANDWIDTH AND DENSITY,” the disclosure of which is expressly incorporated by reference herein in its entirety.

### BACKGROUND

### Field

Aspects of the present disclosure relate to integrated circuits (ICs) and, more particularly, to a single hybrid system-on-chip (SoC) die structure with high memory bandwidth and density.

### Background

Memory is a vital component for computing devices, wireless communications devices, and other like computing devices. For example, a cell phone may integrate memory as part of an application processor, such as a system-on-chip (SoC) including a central processing unit (CPU) and a graphics processing unit (GPU). Successful operation of some wireless applications depends on the availability of high capacity and low latency memory solutions for scalability of CPU/GPU workload. A semiconductor memory device solution for providing a high capacity, low latency, and high bandwidth memory is an existing goal for system designers.

Semiconductor memory devices include, for example, a dynamic random-access memory (DRAM). A DRAM memory cell includes one transistor and one capacitor, thereby providing a high degree of integration. DRAM-on-logic, however, is hindered by temperature envelope limitations of DRAM on hotspots on the CPU/GPU of an SoC. In practice, memory intensive applications (e.g., artificial intelligence (AI)) consume extensive amounts of DRAM, which involve cell retention time control due to refresh specifications of DRAM devices. Unfortunately, thermal generation from an SoC logic device complicates cell retention time control. Therefore, a solution for overcoming the DRAM thermal issue caused by a thermal hot spot region of SoC logic devices is desired.

### SUMMARY

A three-dimensional (3D) stacked chip package is described. The 3D stacked chip package includes a die having a wide input/output (IO) logic die area and a system-on-chip (SoC) logic die area isolated from the wide IO logic die area. The 3D stacked chip package also includes a memory stack on the wide IO logic area of the die. The 3D stacked chip package further includes a package substrate supporting the die.

A method for fabricating a system-on-chip (SoC) package having a hybrid die structure is described. The method includes forming a die having a wide input/output (IO) logic die area and a system-on-chip (SoC) logic die area isolated from the wide IO logic die area on a package substrate supporting the die. The method also includes forming a memory stack on the wide IO logic area of the die.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-chip (SoC), including a hybrid SoC die structure, in accordance with certain aspects of the present disclosure.

FIG. 2 shows a cross-sectional view of a stacked integrated circuit (IC) package, of the host system-on-chip (SoC) of FIG. 1.

FIG. 3 shows a cross-sectional view illustrating the stacked integrated circuit (IC) package of FIG. 2, incorporated into a wireless device, according to one aspect of the present disclosure.

FIGS. 4A-4C are block diagrams illustrating a system-on-chip (SoC) package having a hybrid SoC die structure, according to various aspects of the present disclosure.

FIG. 5 is a block diagram illustrating a system-on-chip (SoC) package having a hybrid SoC die structure, according to further aspects of the present disclosure.

FIG. 6 is a block diagram illustrating a system-on-chip (SoC) package having a hybrid SoC die structure, according to further aspects of the present disclosure.

FIGS. 7A-7H are cross-sectional diagrams illustrating a process for fabricating the system-on-chip (SoC) package of FIG. 4A, having the hybrid die structure, according to various aspects of the present disclosure.

FIG. 8 is a process flow diagram illustrating a method for fabricating a three-dimensional (3D) stacked chip, according to various aspects of the present disclosure.

FIG. 9 is a block diagram showing an exemplary wireless communications system, in which an aspect of the present disclosure may be advantageously employed.

FIG. 10 is a block diagram illustrating a design workstation used for circuit, layout, and logic design of a semiconductor component such as the three-dimensional (3D) stacked chip disclosed herein.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

Memory is a vital component for wireless communications devices. For example, a cell phone may integrate memory as part of an application processor, such as a system-on-chip (SoC) including one or more processors, e.g., a central processing unit (CPU), a graphics processing unit (GPU), and a neural processing unit (NPU). Successful operation of some wireless applications depends on the availability of a high capacity and low latency memory solution for scalability of processor workload. A semiconductor memory device solution for providing a high capacity, low latency, and high bandwidth memory is an existing goal for system designers.

Semiconductor memory devices include, for example, dynamic random-access memory (DRAM). A DRAM memory cell includes one transistor and one capacitor, thereby providing a high degree of integration. DRAM-on-logic, however, is hindered by temperature envelope limitations of DRAM proximate hotspots on the processors (e.g., CPU, GPU, NPU) of an SoC. Integrating DRAM on hot compute logic including the processors (e.g., CPU, GPU, NPU) is problematic because this hot compute logic prevents, or hinders, cooling of the DRAM junction temperatures. These limitations have led to industry implementation of DRAM in side-by-side configuration with the processors (e.g., CPU, GPU, NPU) of the hot compute logic.

In practice, memory intensive applications (e.g., artificial intelligence (AI)) require extensive amounts of DRAM, which involve cell retention time control due to refresh specifications of DRAM devices. Unfortunately, thermal generation from an SoC logic device complicates cell retention time control. One potential future solution involves directly stacking a three-dimensional (3D) DRAM above a base SoC logic device die area. These potential future solutions of 3D DRAM stacking above the base SoC logic device, however, incur a thermal hot spot of the SoC logic device, which negatively impacts the DRAM retention time, potentially resulting in a DRAM cell failure.

More recently, the number of interconnect levels for circuitry has increased due to the substantial number of devices that are now interconnected in a state-of-the-art processing device, such as a mobile application device. These interconnections include back-end-of-line (BEOL) layers, which may refer to the conductive interconnect layers for electrically coupling to front-end-of-line (FEOL) active devices of an integrated circuit (IC). The various BEOL interconnect layers are formed at corresponding BEOL interconnect levels, in which lower BEOL interconnect levels use thinner metal layers relative to upper BEOL interconnect levels. The BEOL interconnect layers may electrically couple to middle-of-line (MOL) interconnect layers, which interconnect to the FEOL active devices of an IC.

State-of-the-art high bandwidth memory (HBM) DRAM and SoC logic devices are assembled on an interposer. In this configuration, all the connections between the HBM DRAM and SoC logic devices are implemented through the interposer. As the HBM DRAM and SoC logic devices become more complex, however, more interconnect layers are used to provide the electrical connections between the devices. As a result, signal integrity presents a significant burden as the DRAM/SoC devices' frequencies will increase in future generations. Therefore, a solution for overcoming the signal integrity issues as well as the noted DRAM thermal issues caused by a thermal hot spot region of SoC logic devices is desired.

Various aspects of the present disclosure provide a single hybrid system-on-chip (SoC) die structure with high memory bandwidth and density. The process flow for fabrication of a single hybrid SoC die structure with high memory bandwidth and density may further include formation of a thermal isolation layer and/or control circuits. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably. Similarly, the terms “chip,” “chiplet,” and “die” may be used interchangeably.

Various aspects of the present disclosure overcome the noted thermal issues by providing a hybrid die structure including a wide input/output (IO) logic die area from a system-on-chip (SoC) logic area isolated from the wide IO logic area. Modifying the SoC logic device's architecture design by separating the connection structures for a dynamic random-access memory (DRAM) device from the SoC logic device eliminates the use of an interposer and provides performance improvements for both the DRAM and SoC logic devices. These aspects of the present disclosure also provide a significant benefit for supporting an increased number of IO connections specified in future devices by eliminating the interposer. Additionally, separating the hot spot logic region from the stacked DRAM potentially eliminates the performance throttling caused by the thermal control of the SoC logic device. Eliminating the performance throttling significantly improves SoC/DRAM support for AI applications.

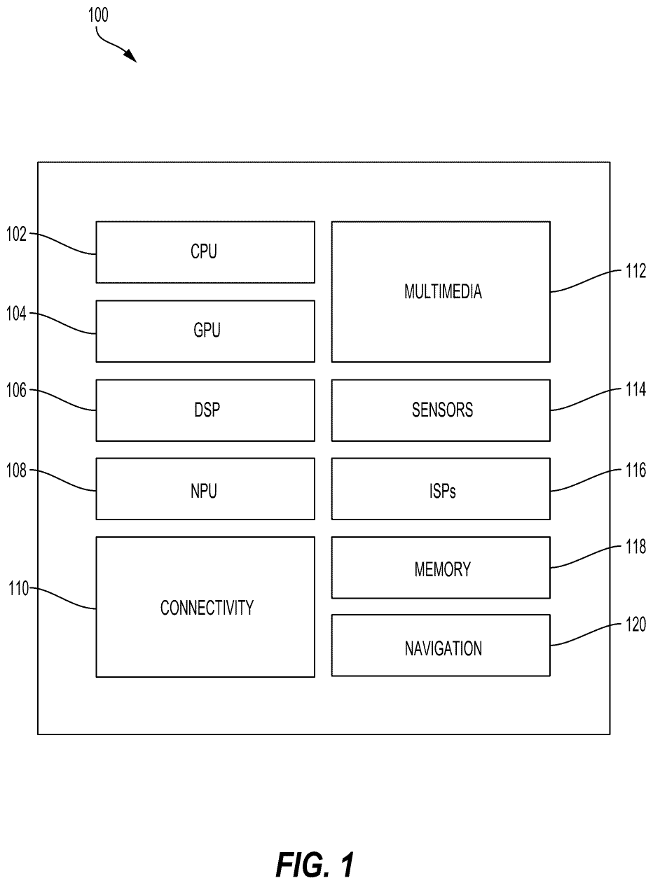

FIG. 1 illustrates an example implementation of a host system-on-chip (SoC) 100, which includes a hybrid SoC die structure for 3D chip stacking, in accordance with certain aspects of the present disclosure. The host SoC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

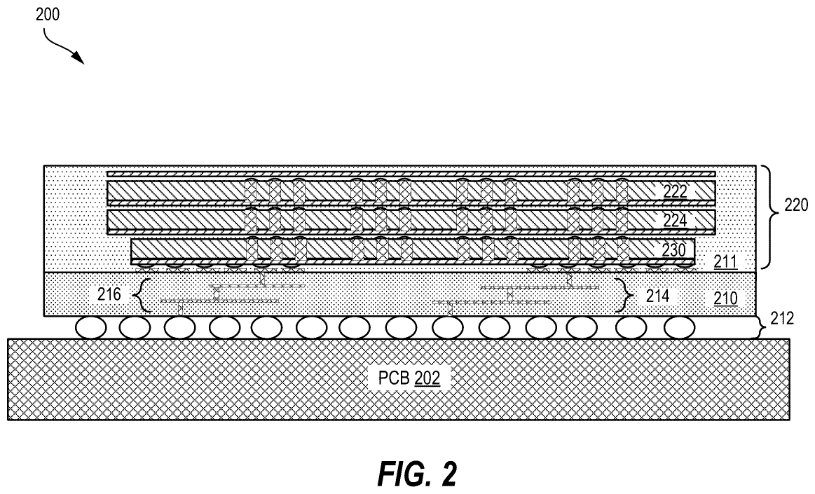

FIG. 2 shows a cross-sectional view of a stacked integrated circuit (IC) package 200 of the host system-on-chip (SoC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the host SoC 100 of FIG. 1.

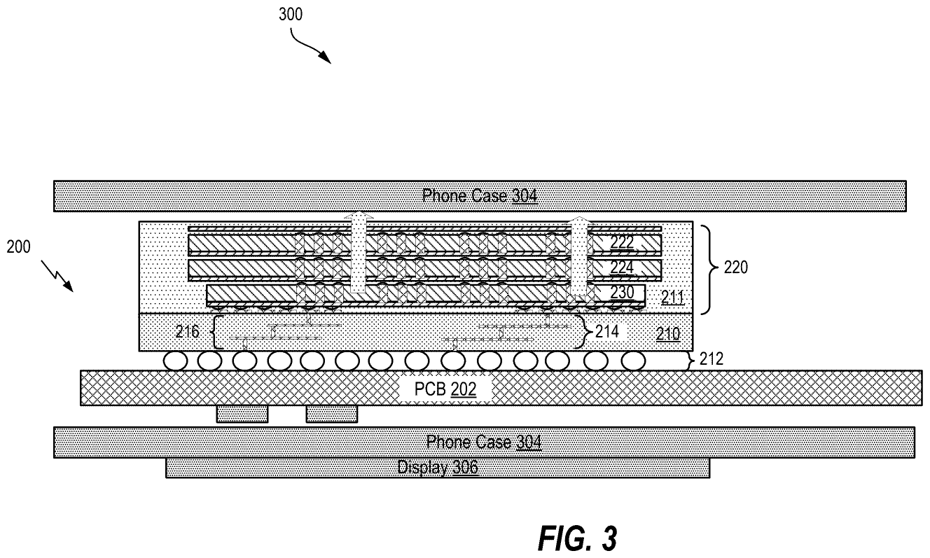

FIG. 3 shows a cross-sectional view illustrating the stacked integrated circuit (IC) package 200 of FIG. 2, incorporated into a wireless device 300, according to one aspect of the present disclosure. As described, the wireless device 300 may include, but is not limited to, a smartphone, tablet, handheld device, or other limited form factor device configured for 5G NR/6G communications. Representatively, the stacked IC package 200 is within a phone case 304, including a display 306.

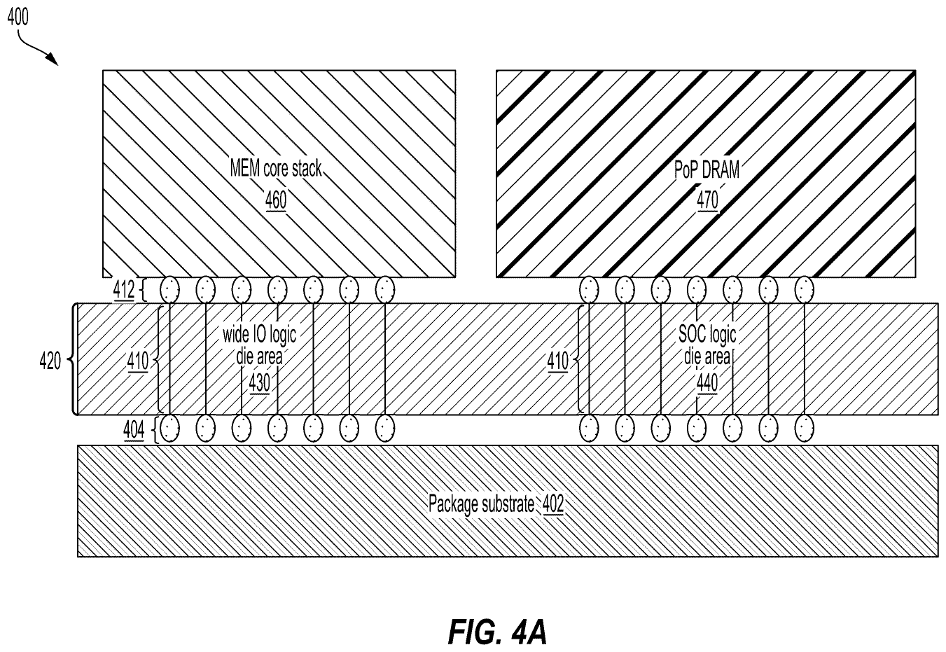

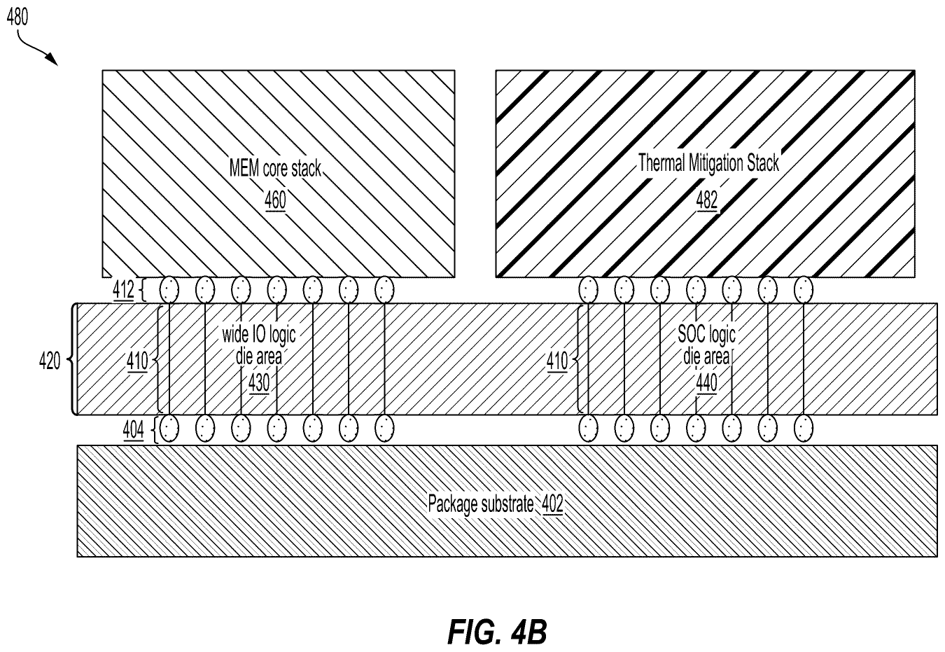

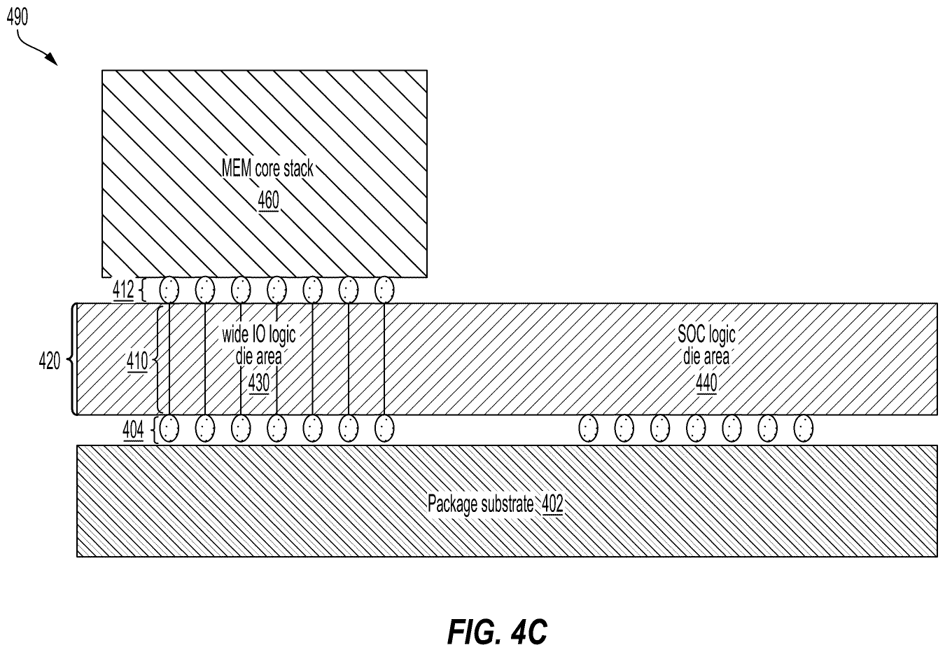

State-of-the-art high bandwidth memory (HBM) dynamic random-access memory (DRAM) and system-on-chip (SoC) logic devices are assembled on an interposer, for example, of the stacked IC package 200 of FIG. 2. In this configuration, all the connections between the HBM DRAM and SoC logic devices are implemented through the interposer. As the HBM DRAM and SoC logic devices become more complex, however, more interconnect layers are used to provide the electrical connections between the devices. As a result, signal integrity presents a significant burden as the DRAM/SoC devices' frequencies will increase in future generations. Therefore, a solution for overcoming the signal integrity issues as well as DRAM thermal issues caused by the thermal hot spot region of SoC logic devices is desired. In various aspects of the present disclosure, a hybrid SoC die structure is integrated in the stacked IC package 200 to support 3D chip stacking, for example, as shown in FIGS. 4A to 7G.

FIGS. 4A-4C are block diagrams illustrating a system-on-chip (SoC) package having a hybrid SoC die structure, according to various aspects of the present disclosure. The SoC package may be referred to as a system-in-package (SIP) in some implementations. As shown in FIG. 4A, an SoC package 400 includes a package substrate 402 having first micro-bumps 404 for supporting a hybrid die structure 420 composed of a wide input/output (IO) logic die area 430 and an SoC logic die area 440. In this configuration, the wide IO logic die area 430 includes second micro-bumps 412 for supporting a memory (MEM) core stack 460 (e.g., a memory stack). For example, the MEM core stack 460 is composed of a high bandwidth memory (HBM) core stack of dynamic random-access memory (DRAM) dies or another like wide IO device. In this configuration, the wide IO logic die area 430 is composed of a high bandwidth memory (HBM) base logic die area.

Additionally, the SoC logic die area 440 includes the second micro-bumps 412 for supporting a package-on-package (POP) DRAM 470 to meet memory bandwidth and/or memory density specifications. In this example, through substrate vias (TSVs) 410 are shown extending through the wide IO logic die area 430 and the SoC logic die area 440 of the hybrid die structure 420. According to various aspects of the present disclosure, the hybrid die structure 420 supports high bandwidth memory (HBM), which improves memory bandwidth as well as memory density flexibility.

Additionally, the hybrid die structure 420 of the SoC package 400 provides a seamless connection between the wide IO logic die area 430 and the SoC logic die area 440 using the TSVs 410 by merging a physical layer (PHY) of the wide IO logic die area 430 with the PHY of the SoC logic die area 440. For example, in an HBM configuration, the hybrid die structure 420 avoids a complex double data rate (DDR) timing mismatch between the MEM core stack 460 and the SoC logic die area 440, because the conventional interposer connection between DRAM memory and SOC dies is eliminated. The hybrid die structure 420 further supports additional DRAM die stacking flexibility to meet memory bandwidth and/or memory density specifications. The hybrid die structure 420 streamlines DRAM controller/PHY design due to the single die design of the SoC package 400.

FIG. 4B is a block diagram illustrating a system-on-chip (SoC) package having a hybrid SoC die structure, according to various aspects of the present disclosure. As shown in FIG. 4B, an SoC package 480 is similar to the SoC package 400, as shown in FIG. 4A and described using similar reference numerals. As shown in FIG. 4B, SoC package 480 replaces the POP DRAM 470 with a dummy thermal mitigation stack 482. In the example, the dummy thermal mitigation stack 482 is placed over the SoC logic die area 440 to enhance thermal dissipation from the SoC logic die area 440. For example, the dummy thermal mitigation stack 482 may be composed of a thermal cooling device or a dummy semiconductor material (e.g., silicon (Si)) to cool hot spots of the SoC logic die area 440. Although a single, dummy thermal mitigation stack 482 is shown, it should be recognized that additionally ones of the dummy thermal mitigation stack 482 may be arranged on the SoC logic die area 440 and/or the wide IO logic die area 430.

FIG. 4C is a block diagram illustrating a system-on-chip (SoC) package having a hybrid SoC die structure, according to various aspects of the present disclosure. As shown in FIG. 4C, an SoC package 490 is similar to the SoC package 400, as shown in FIG. 4A and described using similar reference numerals. As shown in FIG. 4C, SoC package 480 exposes the area above the SoC logic die area 440. This implementation may sacrifice the enhance thermal dissipation from the SoC logic die area 440 provided by the dummy thermal mitigation stack 482, as shown in FIG. 4B.

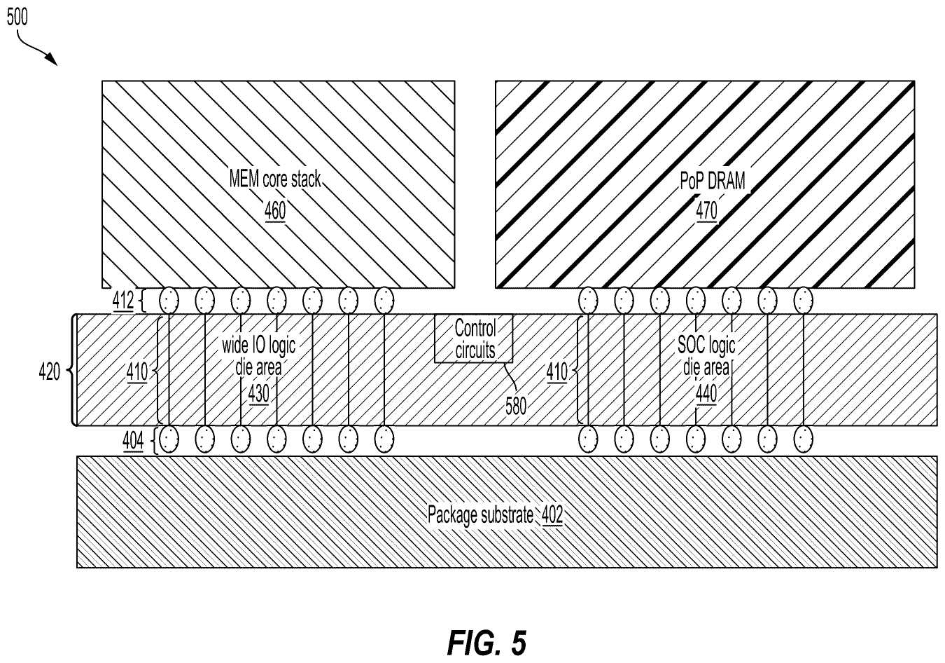

FIG. 5 is a block diagram illustrating a system-on-chip (SoC) package having a hybrid SoC die structure, according to further aspects of the present disclosure. As shown in FIG. 5, an SoC package 500 is like the SoC package 400 of FIG. 4A and is described using similar reference numbers. In various aspects of the present disclosure, the hybrid die structure 420 includes control circuits 580 to separate operation between the wide IO logic die area 430 and the SoC logic die area 440. In this configuration, the control circuits 580 may electrically connect/disconnect the wide IO logic die area 430 and/or the SoC logic die area 440 depending on an operation mode. For example, the control circuits 580 may be configured to deactivate the wide IO logic die area 430 and/or the SoC logic die area 440 of the hybrid die structure 420 depending on a power savings mode.

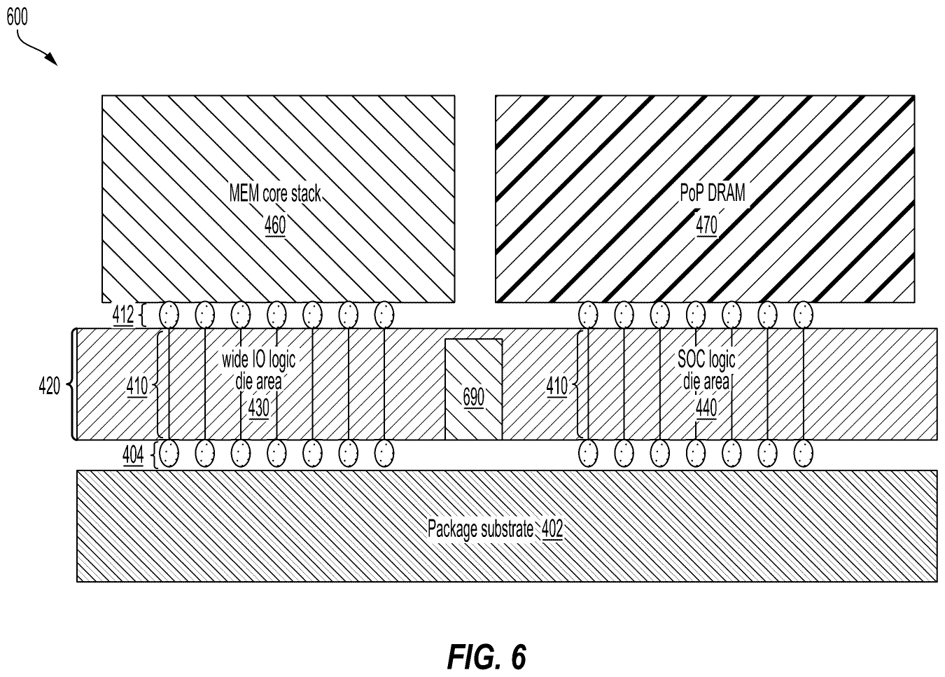

FIG. 6 is a block diagram illustrating a system-on-chip (SoC) package having a hybrid SoC die structure, according to further aspects of the present disclosure. As shown in FIG. 6, an SoC package 600 is like the SoC package 400 of FIG. 4A and is described using similar reference numbers. In various aspects of the present disclosure, the hybrid die structure 420 includes an isolation structure 690 to block (or significantly reduce) the wide IO logic die area 430 from thermal dissipation caused by hot spot(s) from the SoC logic die area 440. In this configuration, the isolation structure 690 may be configured as a thermal dissipation block composed of any insulator oxide material or other like thermal interface material. The isolation structure 690 is sized to prevent contact with active circuits (e.g., the gate 432 or the gate 442) on the frontside of the substrate 422.

According to various aspects of the present disclosure, the isolation structure 690 separates the high-power operation (e.g., thermal hot spot) of logic circuits in the

SoC logic die area 440 from the wide IO logic die area 430 to protect the wide IO logic die area 430 and enable successful operation of the MEM core stack 460. In a high bandwidth memory (HBM) configuration, the isolation structure 690 reduces the thermal impact on an HBM dynamic random-access memory (DRAM) or any DRAM above the wide IO logic die area 430. For example, placement of the isolation structure 690 blocks a thermal hot spot generated by the SoC logic die area 440, which helps maintain a memory cell retention time of the MEM core stack 460 and reduces memory cell failure.

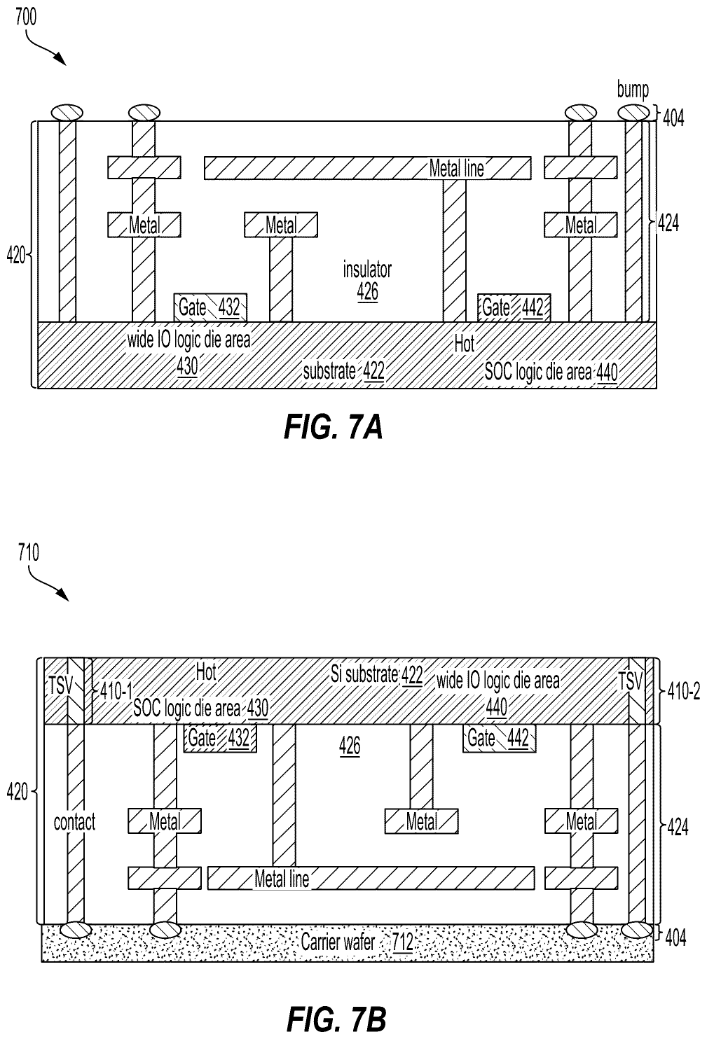

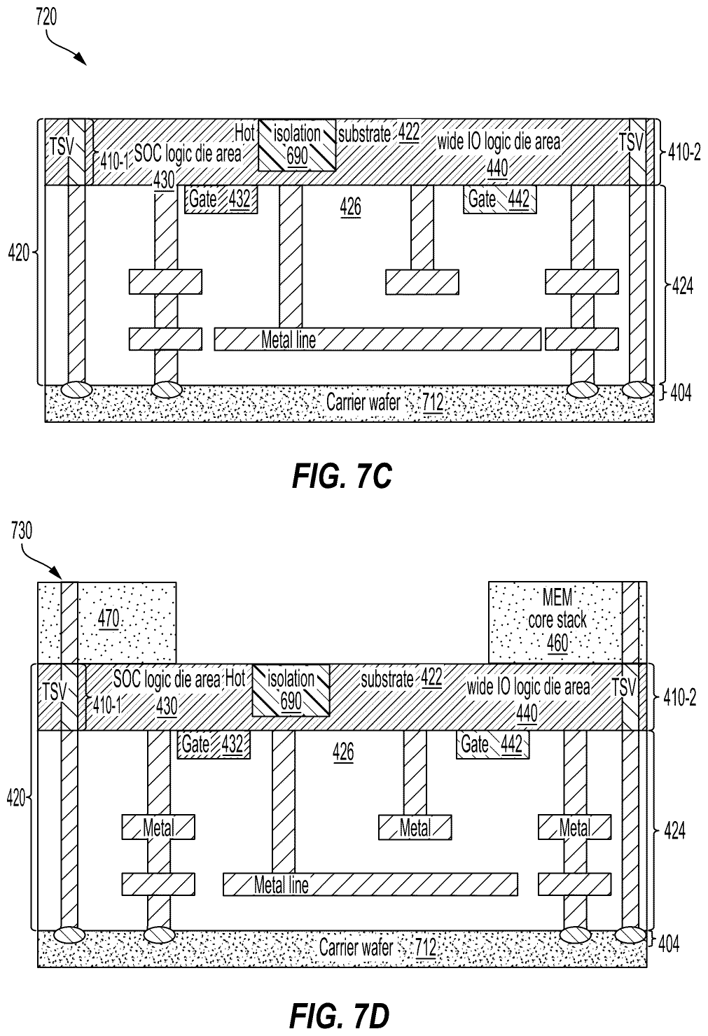

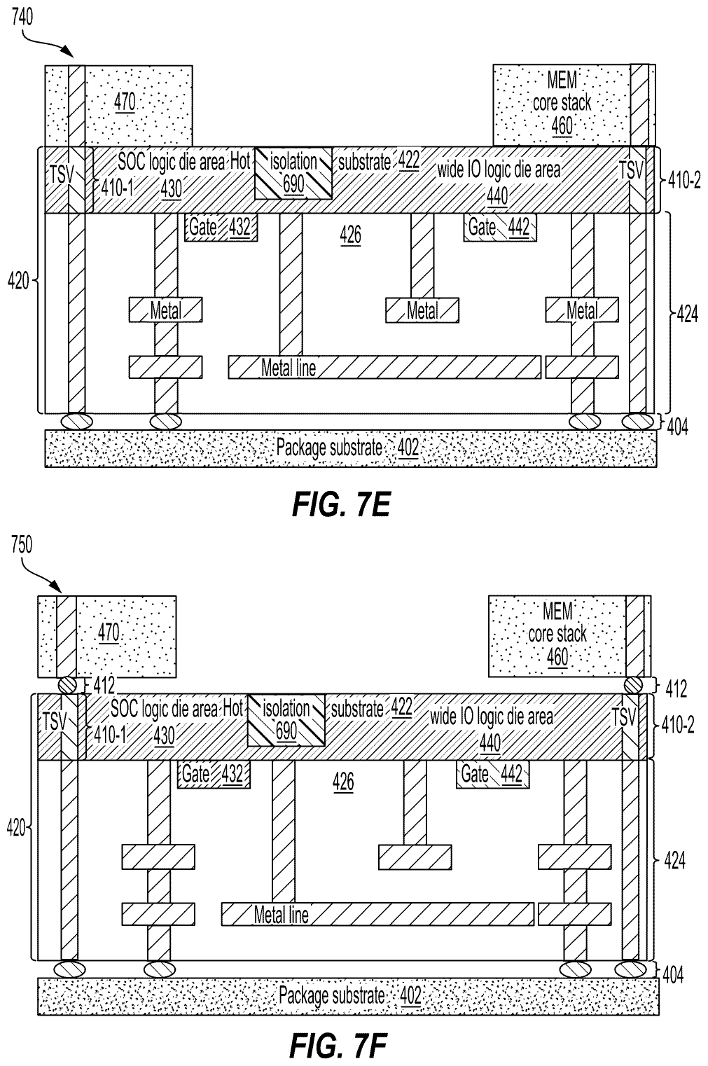

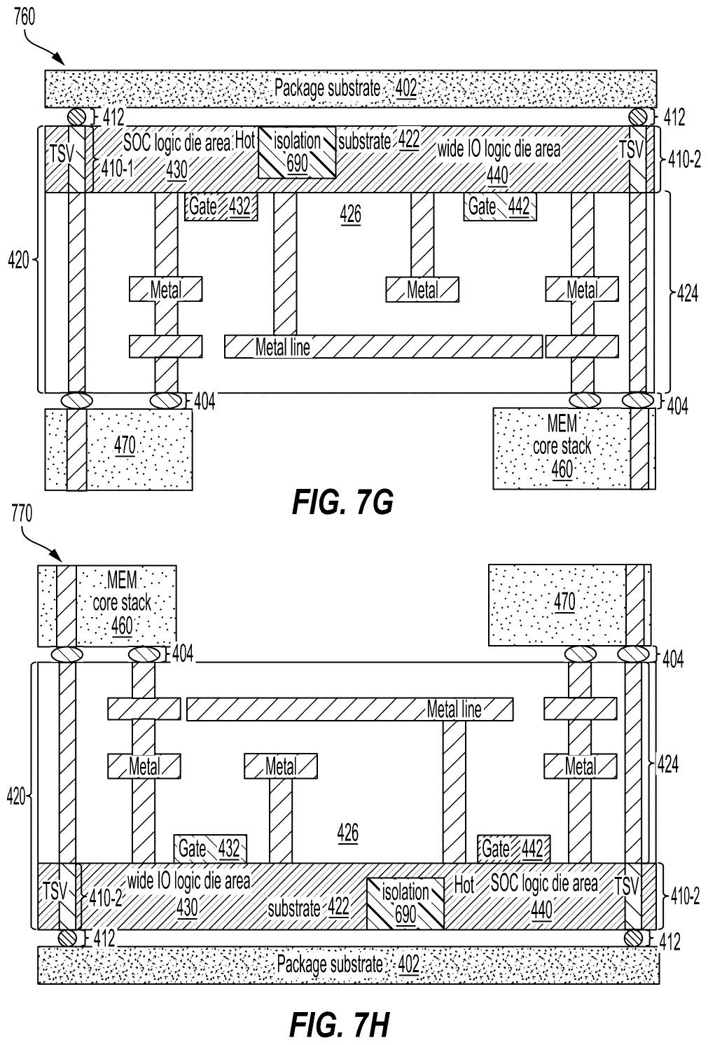

A process of fabricating a system-on-chip (SoC) package that includes a hybrid die structure is shown in FIGS. 7A-7H. FIGS. 7A-7H are cross-sectional diagrams illustrating a process for fabricating the SoC package 400 of FIG. 4A, having the hybrid die structure 420, according to various aspects of the present disclosure.

FIG. 7A illustrates a first step 700 for fabricating the SoC package 400 of FIG. 4A, having the hybrid die structure 420. In various aspects of the present disclosure, a smart chip device front-end-of-line (FEOL) process forms the hybrid die structure 420, including the wide IO logic die area 430 and the SoC logic die area 440 in a substrate 422 (e.g., silicon (Si)). The substrate 422 (e.g., die substrate) includes a first gate 432 on the wide IO logic die area 430 and a second gate 442 on the SoC logic die area 440. This FEOL process is followed by a middle-of-line (MOL)/back-end-of-line (BEOL) process to form a BEOL structure 424 in an insulator layer 426 and complete formation of the hybrid die structure 420. Additionally, the first micro-bumps 404 are formed on the insulator layer 426 and contacted to interconnects of the BEOL structure 424 of the hybrid die structure 420.

FIG. 7B illustrates a second step 710 for fabricating the SoC package 400 of FIG. 4A, having the hybrid die structure 420, according to various aspects of the present disclosure. The second step 710 illustrates bonding of a carrier wafer 712 to the insulator layer 426 of the hybrid die structure 420 after flipping the hybrid die structure 420 to enable backside processing. Additionally, the substrate 422 is subjected to a backside grinding process followed by formation of the through substrate vias (TSVs) 410-1 and 410-2 in the substrate 422.

FIG. 7C illustrates a third step 720 for fabricating the SoC package 400 of FIG. 4A, having the hybrid die structure 420, according to various aspects of the present disclosure. The third step 720 illustrates formation of the isolation structure 690 in the substrate 422 to protect the wide IO logic die area 430 from thermal dissipation caused by hot spot(s) in the SoC logic die area 440, as shown in FIG. 6. The third step 720 may include a photolithography/etch step of the substrate 422 to define the isolation structure 690. Next, an insulator material deposition is performed followed by a chemical mechanical polish of a surface of the substrate to complete formation of the isolation structure 690. Alternatively, a timed insulator etch of the substrate 422 forms a final trench type isolation to provide the isolation structure 690. According to various aspects of the present disclosure, the isolation structure 690 may be configured as a thermal dissipation block composed of any insulator oxide material or other like thermal interface material as the insulator material.

FIG. 7D illustrates a fourth step 730 for fabricating the SoC package 400 of FIG. 4A, having the hybrid die structure 420, according to various aspects of the present disclosure. The fourth step 730 illustrates stacking of the MEM core stack 460 (e.g., HBM DRAM) on a backside of the substrate 422. Additionally, stacking of the POP DRAM 470 (or the dummy thermal mitigation stack 482) utilizing die to wafer hybrid bonding is also illustrated. Alternatively, after micro bump formation, HBM DRAM stacking is also possible. Wafer to wafer hybrid bonding or die to die hybrid bonding is also possible. For POP or any DRAM stacking on the SoC logic die area 440 or the wide IO logic die area 430, a collapsible (e.g., C4) bump or other like bump is also possible. According to various aspects of the present disclosure, stacking of DRAM/SoC devices is performed using micro-bump stacking/die to die hybrid bonding/wafer to wafer hybrid bonding, or the like. Additionally, separate thermal dissipation devices (e.g., the dummy thermal mitigation stack 482) may be utilized, including a thermal dissipation device for the wide IO logic die area 430 and another thermal dissipation device to compensate for the hot spot area of the SoC logic die area 440.

FIG. 7E illustrates a fifth step 740 for fabricating the SoC package 600 of FIG. 6, having the hybrid die structure 420, according to various aspects of the present disclosure. The fifth step 740 illustrates a final stacking of a frontside of the hybrid die structure 420 on the package substrate 402 using the first micro-bumps 404 to contact the package substrate to the interconnects of the BEOL structure 424. In this example, the MEM core stack 460 and the POP DRAM 470 are stacked on the backside of the substrate 422 using hybrid bonding to complete formation of the SoC package 600, as shown in FIG. 6.

FIG. 7F illustrates a sixth step 750 for fabricating the SoC package 600 of FIG. 6, having the hybrid die structure 420, according to various aspects of the present disclosure. The sixth step 750 illustrates a final stacking of a frontside of the hybrid die structure 420 on the package substrate 402 using the first micro-bumps 404 to contact the package substrate 402 to the interconnects of the BEOL structure 424. In this example, the MEM core stack 460 and the POP DRAM 470 are stacked on the backside of the substrate 422 using the second micro-bumps 412 to complete formation of the SoC package 600, as shown in FIG. 6.

FIG. 7G illustrates a seventh step 760 for fabricating the SoC package 600 of FIG. 6, having the hybrid die structure 420, according to various aspects of the present disclosure. The seventh step 760 illustrates a final stacking of the backside of the substrate 422 of the hybrid die structure 420 on the package substrate 402 using the second micro-bumps 412, which are formed using a standard bump process. In this example, the MEM core stack 460 and the POP DRAM 470 are stacked on the frontside of the hybrid die structure 420 using the first micro-bumps 404 to complete formation of the SoC package 600, as shown in FIG. 6.

FIG. 7H illustrates an eighth step 770 for fabricating the SoC package 600 of FIG. 6, having the hybrid die structure 420, according to various aspects of the present disclosure. The eighth step 770 illustrates repositioning of the final stacking of the backside of the substrate 422 of the hybrid die structure 420 on the package substrate 402 using the second micro-bumps 412, as shown in FIG. 7G. FIG. 7H further illustrates further illustrates rotating (e.g., 180°) of the SoC package 600. Additionally, the positions of the package substrate 402 and the MEM core stack 460 and the POP DRAM 470 are matched the hybrid die structure 420 of the SoC package 600, as shown in FIG. 6.

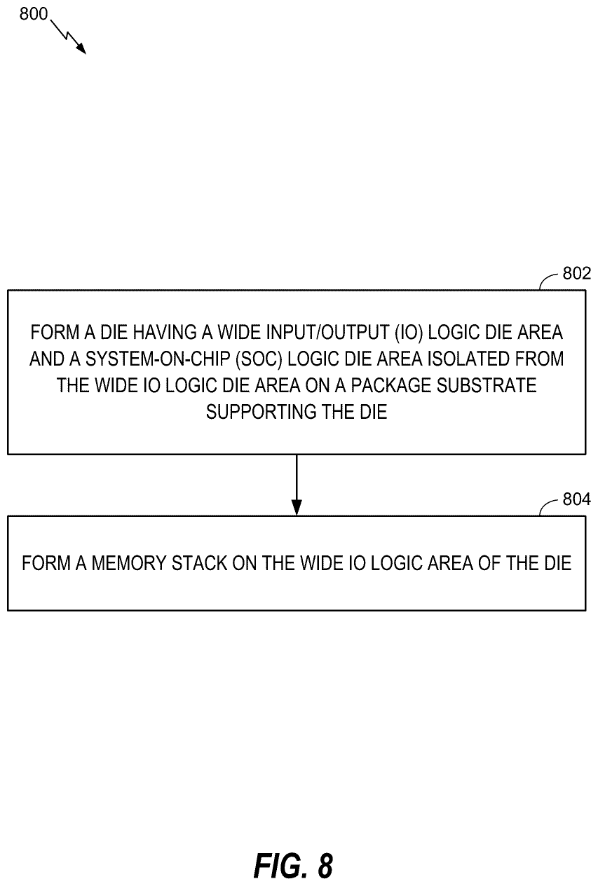

FIG. 8 is a process flow diagram illustrating a method 800 for fabricating a system-on-chip (SoC) package having the hybrid die structure, according to various aspects of the present disclosure. The method 800 begins at block 802, in which a die is form having a wide input/output (IO) logic die area and a system-on-chip (SoC) logic die area isolated from the wide IO logic die area on a package substrate supporting the die. For example, as shown in FIGS. 7A and 7B, a smart chip device FEOL process forms the hybrid die structure 420, including the wide IO logic die area 430 and the SoC logic die area 440 in the substrate 422. The substrate 422 includes the first gate 432 on the wide IO logic die area 430 and the second gate 442 on the SoC logic die area 440. This FEOL process is followed by an MOL/BEOL process to form the BEOL structure 424 in the insulator layer 426 and complete formation of the hybrid die structure 420. Additionally, the first micro-bumps 404 are formed on the insulator layer 426 and contacted to interconnects of the BEOL structure 424 of the hybrid die structure 420.

At block 804, a memory stack is form on the wide IO logic area of the die. For example, FIGS. 7D-7F illustrate stacking of the MEM core stack 460 (e.g., HBM DRAM) on a backside of the substrate 422. Additionally, stacking of the POP DRAM 470 (of the dummy thermal mitigation stack 482) utilizing die to wafer hybrid bonding is also illustrated. The fifth step 740 illustrates a final stacking of a frontside of the hybrid die structure 420 on the package substrate 402 using the first micro-bumps 404 to contact the package substrate to the interconnects of the BEOL structure 424.

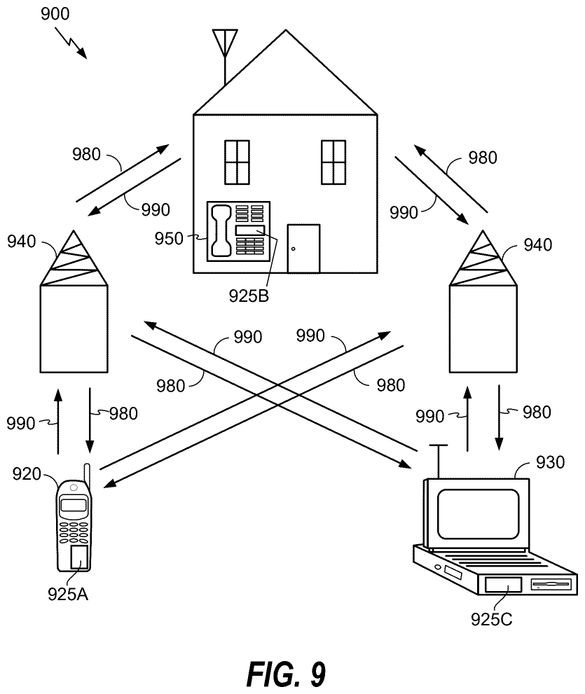

FIG. 9 is a block diagram showing an exemplary wireless communications system 900, in which an aspect of the present disclosure may be advantageously employed. For purposes of illustration, FIG. 9 shows three remote units 920, 930, and 950, and two base stations 940. It will be recognized that wireless communications systems may have many more remote units and base stations. Remote units 920, 930, and 950 include integrated circuit (IC) devices 925A, 925B, and 925C that include the disclosed 3D stacked chip. It will be recognized that other devices may also include the disclosed 3D stacked chip, such as the base stations, switching devices, and network equipment. FIG. 9 shows forward link signals 980 from the base stations 940 to the remote units 920, 930, and 950, and reverse link signals 990 from the remote units 920, 930, and 950 to the base stations 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 9 illustrates remote units according to the aspects of the present disclosure, the disclosure is not limited to these exemplary illustrated units. Aspects of the present disclosure may be suitably employed in many devices, which include the disclosed 3D stacked chip.

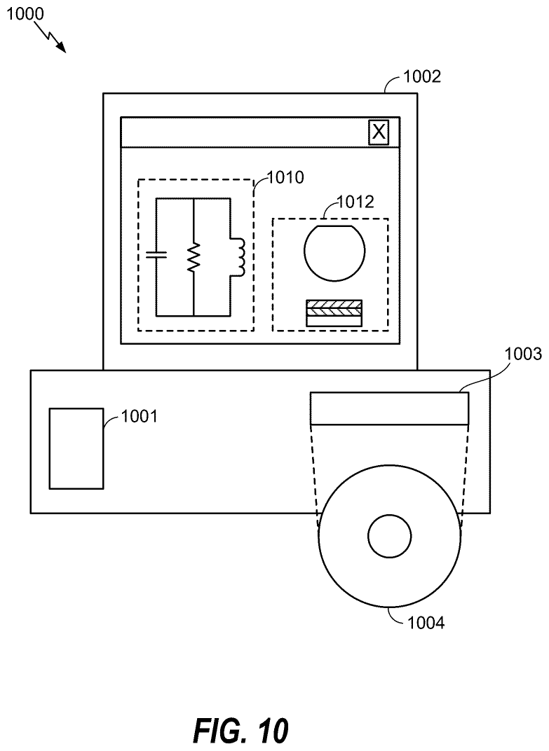

FIG. 10 is a block diagram illustrating a design workstation 1000 used for circuit, layout, and logic design of a semiconductor component, such as the 3D stacked chip disclosed above. The design workstation 1000 includes a hard disk 1001 containing operating system software, support files, and design software such as Cadence or OrCAD. The design workstation 1000 also includes a display 1002 to facilitate design of a circuit 1010 or a semiconductor component 1012, such as the 3D stacked chip. A storage medium 1004 is provided for tangibly storing the design of the circuit 1010 or the semiconductor component 1012 (e.g., the 3D stacked chip). The design of the circuit 1010 or the semiconductor component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the semiconductor component 1012 by decreasing the number of processes for designing semiconductor wafers.

Implementation examples are described in the following numbered clauses:
1. A three-dimensional (3D) stacked chip package, comprising:
   a die having a wide input/output (IO) logic die area and a system-on-chip (SoC) logic die area isolated from the wide IO logic die area;
   a memory stack on the wide IO logic area of the die; and
   a package substrate supporting the die.
2. The 3D stacked chip package of clause 1, in which the wide IO logic die area comprises a high bandwidth memory (HBM) base logic die area.
3. The 3D stacked chip package of any of clauses 1 or 2, in which the memory stack comprises a high bandwidth memory (HBM) dynamic random-access memory (DRAM) stack.
4. The 3D stacked chip package of any of clauses 1-3, further comprising a package-on-package (POP) dynamic random-access memory (DRAM) stacked on the SoC logic die area.
5. The 3D stacked chip package of any of clauses 1-4, further comprising a thermal mitigation stack on the SoC logic die area.
6. The 3D stacked chip package of clause 5, in which the thermal mitigation stack comprises a dummy semiconductor material.
7. The 3D stacked chip package of clause 5, in which the thermal mitigation stack comprises a thermal cooling device.
8. The 3D stacked chip package of any of clauses 1-7, in which the package substrate supports a frontside of the die or a backside of a die substrate.
9. The 3D stacked chip package of any of clauses 1-8, in which the memory stack is on a frontside of the die or a backside of a die substrate.
10. The 3D stacked chip package of any of clauses 1-9, further comprising: first micro-bumps between the package substrate and the die; and second micro-bumps between the memory stack and the die.
11. A method for fabricating a system-on-chip (SoC) package having a hybrid die structure, comprising:
   forming a die having a wide input/output (IO) logic die area and a system-on-chip (SoC) logic die area isolated from the wide IO logic die area on a package substrate supporting the die; and
   forming a memory stack on the wide IO logic area of the die.
12. The method of clause 11, in which the wide IO logic die area comprises a high bandwidth memory (HBM) base logic die area.
13. The method of any of clauses 11 or 12, in which the memory stack comprises a high bandwidth memory (HBM) dynamic random-access memory (DRAM) stack.
14. The method of any of clauses 11-13, further comprising stacking a package-on-package (POP) dynamic random-access memory (DRAM) on the SoC logic die area.
15. The method of any of clauses 11-14, further comprising forming a thermal mitigation stack on the SoC logic die area.
16. The method of clause 15, in which the thermal mitigation stack comprises a dummy semiconductor material.
17. The method of clause 15, in which the thermal mitigation stack comprises a thermal cooling device.
18. The any of clauses 11-17, in which the package substrate supports a frontside of the die or a backside of a die substrate.
19. The method of any of clauses 11-18, in which the memory stack is on a frontside of the die or a backside of a die substrate.
20. The method of any of clauses 11-19, further comprising: forming first micro-bumps between the package substrate and the die; and forming second micro-bumps between the memory stack and the die.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random-access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described but is to be accorded the widest scope consistent with the principles and novel features disclosed.

What is claimed is:

1. A three-dimensional (3D) stacked chip package, comprising:
a die having a wide input/output (IO) logic die area and a system-on-chip (SoC) logic die area isolated from the wide IO logic die area;
a memory stack on the wide IO logic area of the die; and
a package substrate supporting the die.

2. The 3D stacked chip package of claim 1, in which the wide IO logic die area comprises a high bandwidth memory (HBM) base logic die area.

3. The 3D stacked chip package of claim 1, in which the memory stack comprises a high bandwidth memory (HBM) dynamic random-access memory (DRAM) stack.

4. The 3D stacked chip package of claim 1, further comprising a package-on-package (POP) dynamic random-access memory (DRAM) stacked on the SoC logic die area.

5. The 3D stacked chip package of claim 1, further comprising a thermal mitigation stack on the SoC logic die area.

6. The 3D stacked chip package of claim 5, in which the thermal mitigation stack comprises a dummy semiconductor material.

7. The 3D stacked chip package of claim 5, in which the thermal mitigation stack comprises a thermal cooling device.

8. The 3D stacked chip package of claim 1, in which the package substrate supports a frontside of the die or a backside of a die substrate.

9. The 3D stacked chip package of claim 1, in which the memory stack is on a frontside of the die or a backside of a die substrate.

10. The 3D stacked chip package of claim 1, further comprising:
first micro-bumps between the package substrate and the die; and
second micro-bumps between the memory stack and the die.

11. A method for fabricating a system-on-chip (SoC) package having a hybrid die structure, comprising:
forming a die having a wide input/output (IO) logic die area and a system-on-chip (SoC) logic die area isolated from the wide IO logic die area on a package substrate supporting the die; and
forming a memory stack on the wide IO logic area of the die.

12. The method of claim 11, in which the wide IO logic die area comprises a high bandwidth memory (HBM) base logic die area.

13. The method of claim 11, in which the memory stack comprises a high bandwidth memory (HBM) dynamic random-access memory (DRAM) stack.

14. The method of claim 11, further comprising stacking a package-on-package (POP) dynamic random-access memory (DRAM) on the SoC logic die area.

15. The method of claim 11, further comprising forming a thermal mitigation stack on the SoC logic die area.

16. The method of claim 15, in which the thermal mitigation stack comprises a dummy semiconductor material.

17. The method of claim 15, in which the thermal mitigation stack comprises a thermal cooling device.

18. The method of claim 11, in which the package substrate supports a frontside of the die or a backside of a die substrate.

19. The method of claim 11, in which the memory stack is on a frontside of the die or a backside of a die substrate.

20. The method of claim 11, further comprising:
forming first micro-bumps between the package substrate and the die; and
forming second micro-bumps between the memory stack and the die.
